(19) United States
(12) Patent Application Publication
(10) Pub. No.: US 2018/0226377 A1
(43) Pub. Date: Aug. 9, 2018

(54) ROBUST INTERMETALLIC COMPOUND LAYER INTERFACE FOR PACKAGE IN PACKAGE EMBEDDING

(71) Applicant: INTEL IP CORPORATION, SANTA CLARA, CA (US)

(72) Inventors: Christian GEISSLER, Teugn (DE); Georg SEIDEMANN, Landshut (DE)

(21) Appl. No.: 15/748,115

(22) PCT Filed: Aug. 27, 2015
(86) PCT No.: PCT/US2015/047302

§ 371 Date: Jan. 26, 2018

(51) Int. Cl. H01L 25/065; H01L 23/00; H01L 23/498; H01L 21/02; H05K 1/11

(52) U.S. Cl. CPC H01L 25/065; H01L 24/29; H01L 23/49816; H01L 23/562; H01L 21/02362; H01L 2924/01029; H05K 1/111; H01L 24/27; H01L 2924/15331; H01L 2924/35121; H01L 24/32

(57) ABSTRACT

Embodiments may relate to an embedded package having a diffusion barrier layer may be placed between a copper (Cu) pad and a solder ball inside the embedded package. During the solder reflow process, an intermetallic compound (IMC) layer is created that does not come into contact with the Cu, so that subsequent high temperatures applied to the embedded package may not cause the Cu to be consumed through diffusion. Other embodiments may be described and/or claimed.

### FIELD

Embodiments of the present disclosure generally relate to the field of package assemblies, particularly packages with other packages or elements embedded therein.

### BACKGROUND

The demand of system in package (SiP) solutions for mobile and wearable markets is dramatically rising. This in turn increases the demand not only for integration of active and passive silicon dies like integrated circuits (ICs) and integrated passive devices (IPDs), but also for integration and packaging of already packaged dies and systems.

### BRIEF DESCRIPTION OF THE DRAWINGS

FIG. 1 illustrates an example of an intermetallic compound (IMC) interface on a copper (Cu) pad, in accordance with embodiments.

FIG. 2 illustrates an example of an IMC interface on a Cu under-bump metallization (UBM), in accordance with embodiments.

FIG. 3 illustrates an example of an interface assembly at a solder point, in accordance with embodiments.

FIG. 4 illustrates an example of a process for manufacturing an IMC interface for a package-in-package assembly, in accordance with embodiments.

FIG. 5 illustrates an example of package-in-package embedding, in accordance with embodiments.

FIG. 6 schematically illustrates a computing device, in accordance with embodiments.

### DETAILED DESCRIPTION

Embodiments of the present disclosure generally relate to the field of connecting one or more packages that are themselves embedded inside another package. In particular, to enable an electrical connection, a diffusion barrier layer may be placed between a Cu pad and a solder ball inside the embedded package. During the solder reflow process, an IMC layer may be created that does not come into contact with the Cu, so that subsequent high temperature applied to the embedded package may not cause the Cu to be consumed.

In embodiments, ball grid array (BGA) packages embedded into a system-in-package (SiP) may have a diffusion barrier layer that may be made of electroless nickel/electroless palladium/immersion gold (ENEPIG) on top of the Cu ball pad or Cu UBM. The IMC phase of the solder ball may then be limited to the ENEPIG surface so that Cu diffusion is suppressed during further high temperature exposure. Additional high temperatures applied during SiP packaging, for example during polyimide curing, may not lead to reliability reduction at interface.

The mechanical stress on an ENEPIG layer that may be applied to a solder joint of an embedded package that may be caused by interaction with a printed circuit board (PCB) may be much lower than the stress on an ENEPIG layer in a solder joint having a direct contact with a PCB. This may make the connections using the ENEPIG layer in an embedded package less likely to fail, for example through delamination, cracking, or breaking.

While for ease of understanding, embodiments of a diffusion barrier layer and/or material to be used for a diffusion barrier layer may be described as an ENEPIG layer, in alternative embodiments, the diffusion barrier layer may be practiced with other techniques, such as electroless nickel/molybdenum/phosphorus (NiMoP), with a stack between the Cu surface and the IMC, or with other similarly suitable diffusion suppression materials and/or processes.

For ease of understanding, embodiments of a component a package may be attached to may be described as a PCB. In alternative embodiments, this component may be any substrate.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising.” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an application-specific integrated circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

The manufacture and/or operation of a package may lead to additional thermal budgets applied to those packages embedded within the package. These additional thermal budgets may be far higher than if the embedded packages were standalone packages.

With higher thermal budgets, Cu diffusion may occur at the intermetallic phases between a tin (Sn) solder ball and Cu-ball pad or Cu-UBM. Due to the additional thermal budget experienced during SiP-packaging, the Cu-pad may be completely consumed, with the effect that only the IMC layer is remaining. Furthermore, the SiP-package with its components may have to fulfill reliability criteria for high temperature storage (HTS), temperature cycling, and/or mechanical drop testing. In embodiments, at least 1-2 micrometers (μm) may be remaining Cu under the IMC layer after stress tests. If no Cu remains under the IMC layer, electrical opens, mechanical damage of dielectric layers, etc. may result.

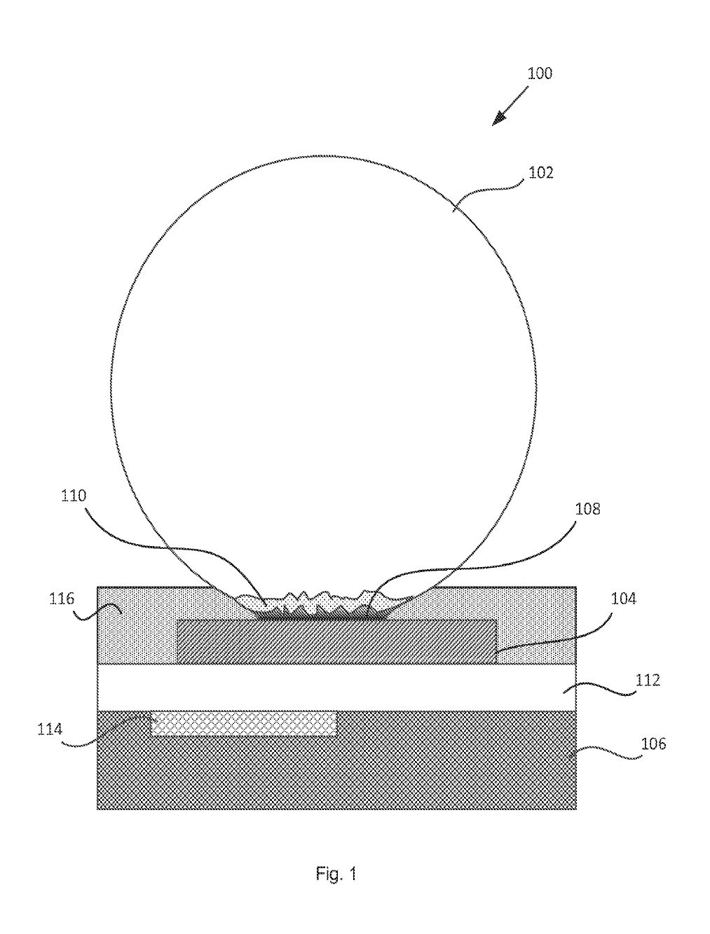

FIG. 1 illustrates an example of an IMC layer interface on a Cu pad, in accordance with embodiments. Package 100 shows one embodiment of an IMC layer interface on a Cu pad that may be used within an embedded package. In embodiments, the solder ball 102 may be connected to a Cu pad 104, and the Cu pad 104 may be connected to silicon die 106 and surrounded by solder mask 116. The solder ball 102 may then be connected to another package where the two packages themselves are contained within a mold compound that may be part of a third package. An example of such a multi-package configuration may be described in more detail below.

In embodiments, the Cu pad 104 may be connected to a dielectric layer 112. In some embodiments, this may be a redistribution layer. Dielectric layer 112 may have multiple layers, and may allow a connection between the Cu pad 104 to a die pad 114 which then may be connected to the silicon die 106.

In embodiments, the solder ball 102 may be made from Sn, from a Sn alloy, or from some other soldering material. In embodiments, ENEPIG layer 108 may be placed on top of the Cu pad 104. In embodiments, the Cu pad 104 may be made from Cu or a Cu alloy. The ENEPIG layer 108 may form a protection layer between the Cu pad 104 and the solder ball 102 which, in embodiments, may completely separate the Cu pad 104 from the solder ball 102 while still allowing electrical conductivity between the Cu pad 104 and the solder ball 102.

In embodiments, the ENEPIG layer 108 may be grown on top of the Cu pad 104. In embodiments, the thickness and/or composition of the ENEPIG layer 108 may be gold (Au) 20-50 nm, palladium (Pd) 100-300 nm and/or nickel (Ni) 3-10 μm, though in other embodiments the ENEPIG layer 108 may include different proportions or ratios of Au, Pd, and/or Ni, and/or include additional materials, metals, and/or alloys.

In embodiments, during the solder ball 102 reflow process, an IMC layer 110 may grow on top of the ENEPIG layer 108 that covers all or part of the Cu pad 104. In embodiments, the IMC layer 110 may grow in the Pd layer of the ENEPIG layer 108. In this embodiment, the IMC layer 110 may be significantly more temperature stable than the IMC layer 110 would be if it was directly coupled with the Cu pad 104. In embodiments, Ni may act as a diffusion barrier against the Cu pad 104, thereby serving as a suitable solution for package in package embedding with an additional high temperature exposure.

In embodiments, adding the ENEPIG layer 108 on the Cu pad 104 may limit the contact between the resulting IMC layer 110 and the Cu pad 104. By limiting the contact, this may result in the Cu pad 104 not being consumed during further high-temperature processing the package may encounter. In embodiments, less Cu diffusion may result in higher thermal stability of the IMC layer interface of the embedded package. With such a Cu reduction, electrical opens and/or mechanical damage, such as cracking of dielectric layers 112, and the like may result. In embodiments, for package-in-package constructions it may be typical for the internal components to reach a temperature exceeding 200° C. for over 30 minutes. In embodiments, there may be more than one of these high-temperature steps.

Another advantage of applying an ENEPIG layer 108 within a package-in-package configuration may include a dramatic lessening of mechanical stress on the interface between the IMC layer 110 and the ENEPIG layer 108. This may lead to a failure during a mechanical drop or a shock test that may occur, for example, during qualification or while in application. In legacy implementations, an ENEPIG layer under a solder junction directly connected to the PCB may tend to fail during mechanical stress like dropping or bending because of the brittleness of the ENEPIG layer. In embodiments, in package construction, if the ENEPIG layer is under a solder joint which is not directly coupled to a PCB, much less mechanical stress appears locally at the ENEPIG layer so typical drop test and bending criteria on the PCB are met. For example in legacy applications, movement, bending, or dropping the PCB may result in connection failures and/or cracking at the connection interface.

While embedding a ball grid array (BGA) package into a fanout wafer level package, high-temperature steps may occur such as polyamide curing. This high-temperature may be outside of the temperature target specification for the embedded package. In legacy implementations, without an ENEPIG layer 108, while exposed to high temperatures the IMC layer 110 may continue to grow and continue to consume the Cu pad 104. In legacy implementations, Cu may continue to be consumed until little to no Cu remains. The IMC layer growth may stop at the Cu liner (not shown), where the liner may typically be Ti or TiN. At that point, the IMC layer may begin to delaminate or to crack.

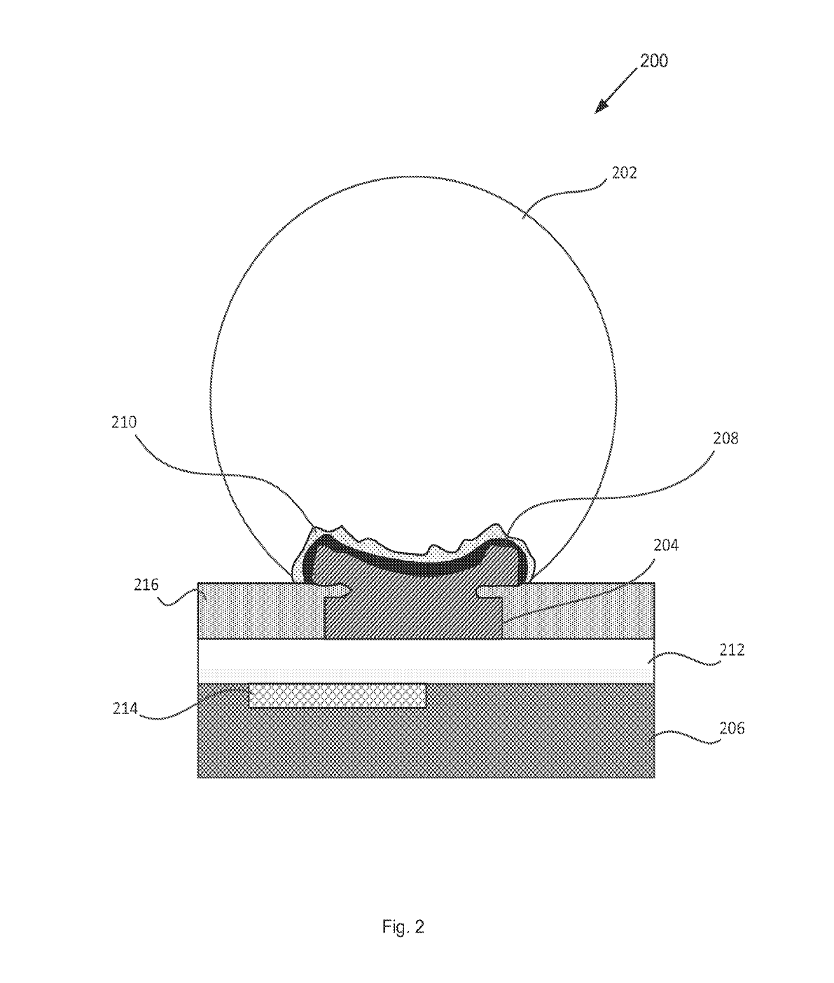

FIG. 2 illustrates an example of an IMC interface on a Cu-UBM, in accordance with embodiments. Specifically, FIG. 2 shows an example embodiment of an IMC interface on a Cu pad that may be used within an embedded package 200, in accordance with various embodiments.

In package 200, which may be similar to package 100, an ENEPIG layer 208, which may be similar to ENEPIG layer 108, may be placed on top of a Cu-UBM 204. This may be accomplished in a number of ways, such as by applying the ENEPIG layer 208 directly to the Cu-UBM 204, or by growing the ENEPIG layer 208 on top of the Cu-UBM 204. A solder ball 202, which may be similar to the solder ball 102, may be placed on top of the Cu-UBM 204 and ENEPIG layer 108. During heating, an IMC layer 210, which may be similar to IMC layer 110, may form on the ENEPIG layer 208. In embodiments, the Cu-UBM 204 may be attached to solder mask 216, which may be similar to the solder mask 116. The Cu-UBM 204 may be attached to a dielectric layer 212, which may be similar to dielectric layer 112. The Cu-UBM 204 may be connected to a die pad 214, which may be similar to die pad 114, which is connected to silicon die 206, which may be similar to silicon die 106.

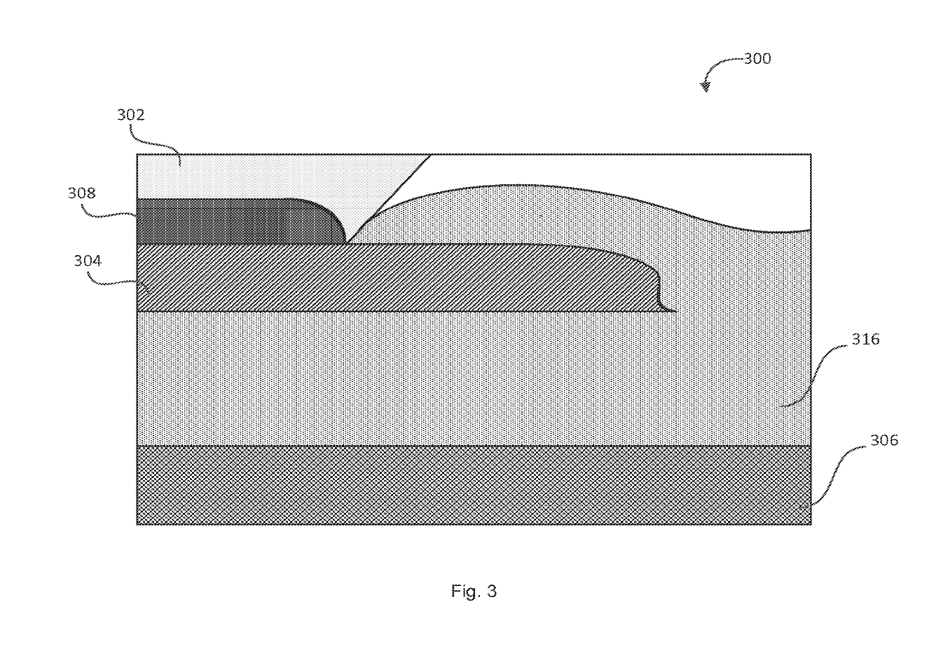

FIG. 3 illustrates an example of an interface assembly at the solder point, in accordance with embodiments. Diagram 300 shows one detailed embodiment of an interface assembly prior to the solder reflow process. The solder ball 302 is placed on top of the ENEPIG layer 308 which is placed on top of the Cu pad 304. In embodiments, solder mask 316 surrounds the Cu pad 304 and abuts the ENEPIG layer 308 such that the solder ball 302 does not come in contact with the Cu pad 304.

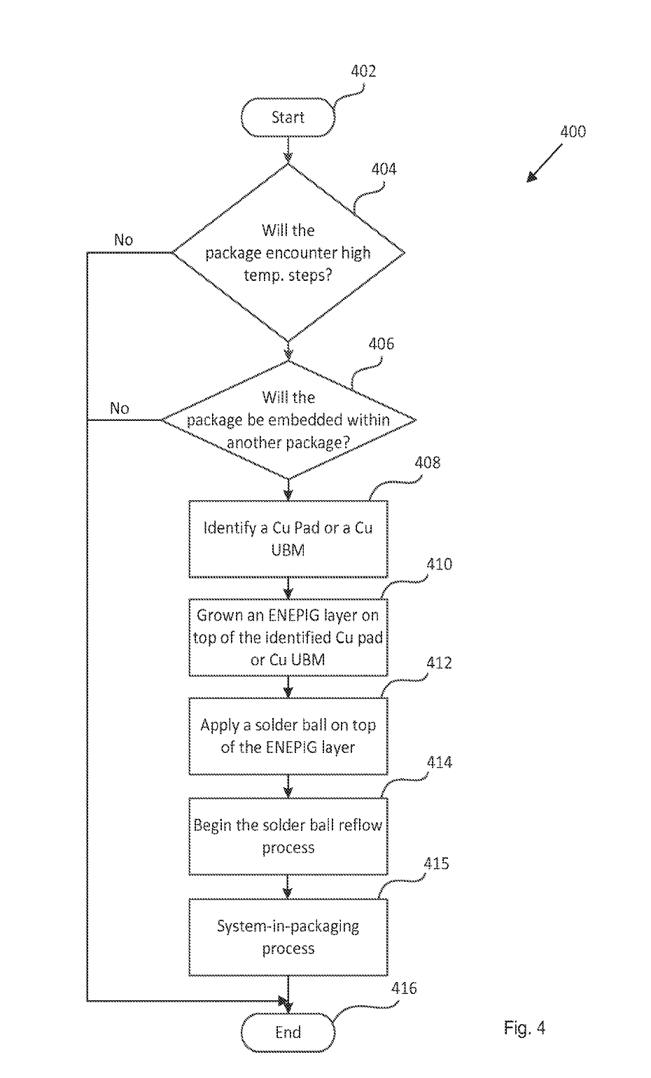

FIG. 4 illustrates an example of a process for manufacturing an interface assembly, in accordance with embodiments. The process 400 may begin at block 402.

At block 404, a determination may be made whether the package will encounter high-temperature that may exceed the typical application case. If not, the process may end at block 416.

Otherwise, if the package will encounter high-temperature steps during packaging or subsequent use, then at block 406 a determination may be made if the package being manufactured will be embedded within another package. If not, the process may end at block 416.

Otherwise, if the package being manufactured will be embedded within another package, then at block 408 a Cu pad or Cu-UBM will be identified. In embodiments, this Cu element may be identified as connected to a solder ball 102 and may be subject to a solder reflow process.

At block 410, an ENEPIG layer may be grown on top of the identified Cu pad or Cu-UBM. In embodiments, the composition of the ENEPIG layer, which may be referred to as electroless nickel palladium gold, may be placed on top of the Cu pad or Cu-UBM to separate the IMC phase of the solder ball to the ENEPIG surface so that Cu diffusion is suppressed for further high-temperature steps, for example during subsequent SiP packaging steps.

In embodiments, an ENEPIG layer may be made from varying proportions of Au, Pd, and Ni. In addition, other elements may also be added to the ENEPIG layer.

At block 412, a solder ball may be applied to the top of the ENEPIG layer. In embodiments, the top of the ENEPIG layer may also be identified as the opposite side of the ENEPIG layer that is in contact with the Cu pad or Cu-UBM. In embodiments, this may include applying solder mask at various locations. In embodiments, solder mask may be applied at different stages in process 400.

At block 414, the solder ball reflow process may begin. In embodiments, the solder ball reflow process may include exposing the solder ball, ENEPIG, and/or Cu pad or Cu-UBM to varying temperatures for varying amounts of time. In embodiments, during this process an IMC layer 110 may be formed between the top of the ENEPIG layer 108 and the solder ball 102. In embodiments this IMC layer 110 may keep the solder ball 102 from contacting all or part of the Cu pad 108 or Cu-UBM 208.

At block 415, the package may be introduced to a SiP manufacturing process.

At block 416, the process 400 may end.

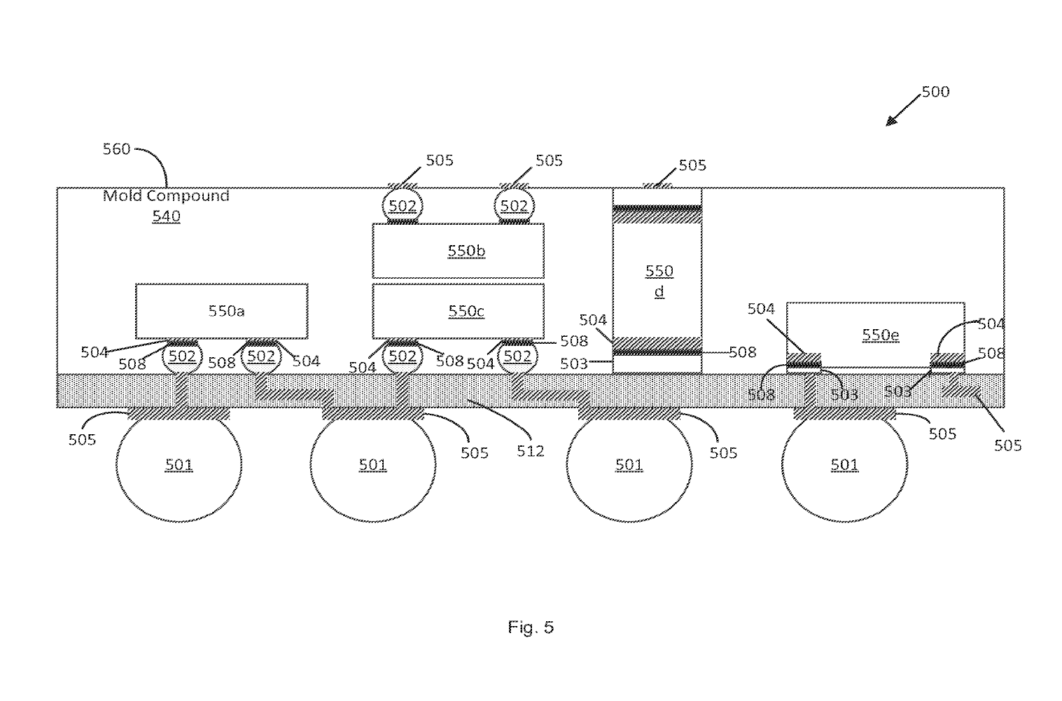

FIG. 5 illustrates an example of package embedding, in accordance with embodiments. Diagram 500 may show one embodiment of package embedding, where package-in-package 560 may include a mold compound 540 and a dielectric layer 512, which may be similar to the dielectric layers of 112, 212. In addition, five sub-packages 550a, 550b, 550c, 550d, 550e that may be connected to the exterior of package-in-package 560 to Cu pads 505. In embodiments, the Cu pads 505, which may be similar to elements 104 and 204, may include Cu and a liner. In embodiments, the Cu pads may be connected to external solder balls 501, which may be similar to the solder balls of 102, 202, which in embodiments may comprise Sn or Sn alloys.

The sub-packages 550a, 550b, 550c, 550d, 550e may include an ENEPIG layer 508, which may be similar to the ENEPIG layer of 108, 208, 308 that may be grown on top of Cu pads 504. Solder balls 502 may be attached to ENEPIG layer 508. In embodiments, during processing where sufficient heat is applied, an IMC layer (not shown) may form between the ENEPIG layer 508 and the Cu pads 504. In embodiments, a solder layer 503 may be placed adjacent to ENEPIG layer 508, as shown in sub-package 550d.

FIG. 5 illustrates just one embodiment of package embedding. In other embodiments may have more or fewer packages or packages in different configurations. Other passive or active devices may be used. In embodiments, not all connections may have an ENEPIG layer.

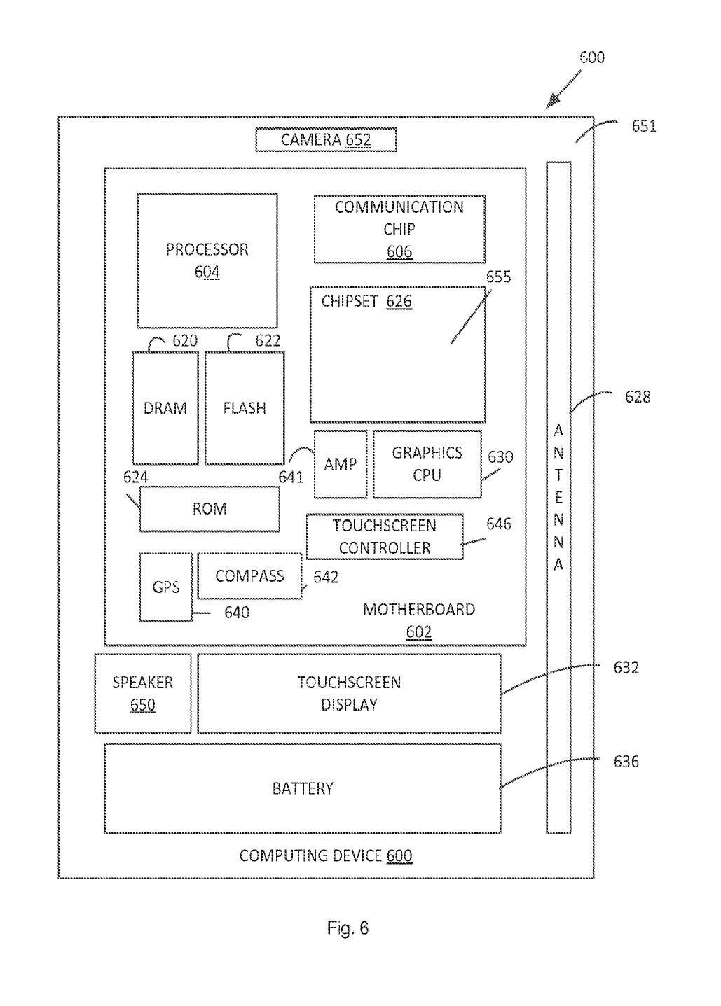

Embodiments of the present disclosure may be implemented into a system using any suitable hardware and/or software to configure as desired. FIG. 6 schematically illustrates a computing device 600 in accordance with one implementation of the invention. The computing device 600 may house a board such as motherboard 602 (i.e. housing 651). The motherboard 602 may include a number of components, including but not limited to a processor 604 and at least one communication chip 606. The processor 604 may be physically and electrically coupled to the motherboard 602. In some implementations, the at least one communication chip 606 may also be physically and electrically coupled to the motherboard 602. In further implementations, the communication chip 606 may be part of the processor 604.

Depending on its applications, computing device 600 may include other components that may or may not be physically and electrically coupled to the motherboard 602. These other components may include, but are not limited to, volatile memory (e.g., DRAM) 620, non-volatile memory (e.g., ROM) 624, flash memory 622, a graphics processor 630, a digital signal processor (not shown), a crypto processor (not shown), a chipset 626, an antenna 628, a display (not shown), a touchscreen display 632, a touchscreen controller 646, a battery 636, an audio codec (not shown), a video codec (not shown), a power amplifier 641, a global positioning system (GPS) device 640, a compass 642, an accelerometer (not shown), a gyroscope (not shown), a speaker 650, a camera 652, and a mass storage device (such as hard disk drive, compact disk (CD), digital versatile disk (DVD), and so forth) (not shown). Further components, not shown in FIG. 6, may include a microphone, a filter, an oscillator, a pressure sensor, or an RFID chip. In embodiments, one or more of the package assembly components 655 may be a package assembly component of an intermetallic compound interface on a Cu pad 100 shown in FIG. 1, or an IMC layer interface on a Cu UBM 200 shown in FIG. 2.

The communication chip 606 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. The communication chip 606 may operate in accordance with a Global System for Mobile Communication (GSM), General Packet Radio Service (GPRS). Universal Mobile Telecommunications System (UMTS), High Speed Packet Access (HSPA), Evolved HSPA (E-HSPA), or LTE network. The communication chip 606 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 606 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 606 may operate in accordance with other wireless protocols in other embodiments.

The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others. In some embodiments, one or more of the communication chips may include an intermetallic compound interface on a Cu pad 100, or an intermetallic compound interface on a Cu UBM 200 as described herein.

The processor 604 of the computing device 600 may include a die in a package assembly having an IMC interface such as, for example, one of package assemblies 100, 200, described herein. The term “processor” may refer to any device or portion of a device that processes electronic data from registers and/or memory to transform that electronic data into other electronic data that may be stored in registers and/or memory.

In various implementations, the computing device 600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data, for example an all-in-one device such as an all-in-one fax or printing device.

### EXAMPLES

Example 1 is an embedded package comprising: a pad; solder electrically coupled to the pad, at least one side of the pad and the solder both within the embedded package; and an intermetallic compound, IMC, grown upon a diffusion barrier on top of the pad, the diffusion barrier positioned between the pad and solder.

Example 2 may include the subject matter of Example 1, wherein the pad is a copper (Cu) pad or a Cu under-ball metallization, UBM.

Example 3 may include the subject matter of Example 2, wherein a material of the diffusion barrier is electroless nickel/electroless palladium/immersion gold, ENEPIG, electroless nickel/molybdenum/phosphorus. NiMoP, or a stack between the Cu surface and the IMC layer.

Example 4 may include the subject matter of Example 2, wherein the IMC is a layer grown on the Cu pad or the Cu UBM.

Example 5 may include the subject matter of Example 1, wherein the diffusion barrier completely separates the pad from the solder so that the pad and solder do not come into direct physical contact.

Example 6 may include the subject matter of Example 1, wherein the diffusion barrier separates the pad from the solder.

Example 7 may include the subject matter of Example 1, wherein the solder is a ball grid array (BGA) solder ball.

Example 8 may include the subject matter of Example 1, wherein the embedded package has no substrate interface.

Example 9 may include the subject matter of Example 1, wherein the package includes a redistribution layer.

Example 10 may include the subject matter of any of Examples 1-9, wherein the diffusion barrier includes a nickel layer between approximately 3 and approximately 10 micrometers thick, a palladium layer between approximately 100 and approximately 300 nanometers thick, or a gold layer between approximately 20 and approximately 50 nanometers thick.

Example 11 is a system with an embedded package assembly, the system comprising: a circuit board; an embedded package assembly electrically coupled with the circuit board, the package assembly comprising: a copper (Cu) pad; solder that is coupled to the pad, at least one side of the pad and the solder both being within the package; and a diffusion barrier between the pad and solder.

Example 12 may include the subject matter of Example 11, wherein the embedded package assembly further comprises an inter-metallic compound (IMC) layer between the diffusion barrier and the solder.

Example 13 may include the subject matter of Example 12, wherein a material of the diffusion barrier is electroless nickel/electroless palladium/immersion gold, ENEPIG, electroless nickel/molybdenum/phosphorus, NiMoP, or a stack between the Cu surface and the IMC layer.

Example 14 may include the subject matter of Example 11, wherein the embedded package is electrically coupled to a second embedded package.

Example 15 may include the subject matter of Example 14, wherein the embedded package and second embedded package are surrounded by a mold compound.

Example 16 may include the subject matter of Example 14, wherein the embedded package and the second embedded package are embedded within a third package.

Example 17 may include the subject matter of Example 14, wherein a first face of the embedded package is connected to a first face of the second embedded package.

Example 18 may include the subject matter of Example 17, further including a second face of the embedded package having one or more second face Cu pads electrically coupled to solder, wherein a second face diffusion barrier is substantially between the one or more second face Cu pads and the solder.

Example 19 may include the subject matter of Example 18, wherein a second face IMC layer is between the second face second face diffusion barrier and the one or more second face Cu pads.

Example 20 may include the subject matter of Example 15, wherein a face of the mold compound is attached to a redistribution layer.

Example 21 may include the subject matter of Example 11, wherein the solder is a ball grid array (BGA).

Example 22 may include the subject matter of Example 11, wherein a material of the diffusion barrier is an ENEPIG layer that includes a nickel layer between approximately 3 and approximately 10 micrometers thick, a palladium layer between approximately 100 and approximately 300 nanometers thick, or a gold layer between approximately 20 and approximately 50 nanometers thick.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1-22. (canceled)

23. An embedded package comprising:
a pad;
solder electrically coupled to the pad, at least one side of the pad and the solder both within the embedded package; and
an intermetallic compound, IMC, grown upon a diffusion barrier on top of the pad, the diffusion barrier positioned between the pad and solder.

24. The package of claim 23, wherein the pad is a copper (Cu) pad or a Cu under-ball metallization, UBM.

25. The package of claim 24, wherein a material of the diffusion barrier is electroless nickel/electroless palladium/immersion gold, ENEPIG, electroless nickel/molybdenum/phosphorus, NiMoP, or a stack between the Cu surface and the IMC layer.

26. The package of claim 24, wherein the IMC is a layer grown on the Cu pad or the Cu UBM.

27. The package of claim 23, wherein the diffusion barrier completely separates the pad from the solder so that the pad and solder do not come into direct physical contact.

28. The package of claim 23, wherein the diffusion barrier separates the pad from the solder.

29. The package of claim 23, wherein the solder is a ball grid array (BGA) solder ball.

30. The package of claim 23, wherein the embedded package has no substrate interface.

31. The package of claim 23, wherein the package includes a redistribution layer.

32. The package of claim 23, wherein the diffusion barrier includes a nickel layer between approximately 3 and approximately 10 micrometers thick, a palladium layer between approximately 100 and approximately 300 nanometers thick, or a gold layer between approximately 20 and approximately 50 nanometers thick.

33. A system with an embedded package assembly, the system comprising:
a circuit board;
an embedded package assembly electrically coupled with the circuit board, the package assembly comprising:
a copper (Cu) pad;
solder that is coupled to the pad, at least one side of the pad and the solder both being within the package; and
a diffusion barrier between the pad and solder.

34. The system of claim 33, wherein the embedded package assembly further comprises an inter-metallic compound (IMC) layer between the diffusion barrier and the solder.

35. The system of claim 34, wherein a material of the diffusion barrier is electroless nickel/electroless palladium/immersion gold, ENEPIG, electroless nickel/molybdenum/phosphorus, NiMoP, or a stack between the Cu surface and the IMC layer.

36. The system of claim 33, wherein the embedded package is electrically coupled to a second embedded package.

37. The system of claim 36, wherein the embedded package and second embedded package are surrounded by a mold compound.

38. The system of claim 36, wherein the embedded package and the second embedded package are embedded within a third package.

39. The system of claim 36, wherein a first face of the embedded package is connected to a first face of the second embedded package.

40. The system of claim 39, further including
a second face of the embedded package having one or more second face Cu pads electrically coupled to solder, wherein a second face diffusion barrier is substantially between the one or more second face Cu pads and the solder.

41. The system of claim 40, wherein a second face IMC layer is between the second face second face diffusion barrier and the one or more second face Cu pads.

42. The system of claim 37, wherein a face of the mold compound is attached to a redistribution layer.

43. The system of claim 33, wherein the solder is a ball grid array (BGA).

44. The system of claim 33, wherein a material of the diffusion barrier is an ENEPIG layer that includes a nickel layer between approximately 3 and approximately 10 micrometers thick, a palladium layer between approximately 100 and approximately 300 nanometers thick, or a gold layer between approximately 20 and approximately 50 nanometers thick.
